(19) United States
(12) Patent Application Publication
(10) Pub. No.: US 2013/0258631 A1
(43) Pub. Date: Oct. 3, 2013

(54) Printed Circuit Assembly

(71) Applicant: Robert Winston Carter, (US)

(72) Inventor: Robert Winston Carter, (US)

(21) Appl. No.: 13/437,451

(22) Filed: Apr. 2, 2012

(51) Int. Cl. H05K 7/00; H01R 4/02

(52) U.S. Cl. 361/791; 439/876

(57) ABSTRACT

A Printed Circuit Assembly has a multiplicity of connectors with each connector containing insulating matrices with each matrix containing a multiplicity of conducting or non-conducting standoffs with each standoff contacting one or more printed circuit boards. The standoffs permit controlled-impedance electrical connections, thermal management and mechanical rigidity of the overall assembly making the assembly suitable for use in any environment including the most harsh extremes.

### BACKGROUND

1. Field of the Invention

This invention relates to the construction of electronic systems using two or more printed circuit boards for application in harsh environments such as moving vehicles or aircraft where vibration and impact acceleration are common.

2. Description of Prior Art

The prior art includes various techniques for building hardware ranging from the early hand-soldered assemblies to wire-wrapped types and up to the recent mainstream approach with multiple-layer printed circuit boards working up into the Gigahertz frequency range. Connection of multiple printed circuit boards has been difficult for decades since a system often includes at least three types of connections: power, digital signals with very fast rise times and analog signals as from audio sources. Howrilka, U.S. Pat. No. 3,271,626 showed the classic cards in a rack. O'brien, US 20070117417A1 showed an advance toward dealing with harsh environments. The Printed Circuit Assembly here was designed to eliminate friction connectors while providing gas-tight connections between circuit boards with a mechanical arrangement suitable to go anywhere.

### SUMMARY OF THE INVENTION

Object and Advantages

Object of patentable novelty and utility taught by this invention are to provide a Printed Circuit Assembly that:

Has a multiplicity of conducting or non-conducting threaded or non-threaded standoff cylinders (1).

Has the cylinders (1) captured in a non-conducting structural matrix material (2) thus forming a between-board connector (6).

Has a multiplicity of printed-circuit boards (4) with each pair of boards (4) connected by a connector made with cylinders (1) contained in the matrix (2).

Has a multiplicity of threaded conducting or non-conducting bolts (3) with each bolt screwed into a column of aligned cylinders (1).

Has a multiplicity of threaded conducting or non-conducting nuts (5) with each nut torqued on each bolt at the base of a column of aligned cylinders (1) to provide gas-tight connections to the printed circuit boards (4).

The invention accomplishes the objectives: a multiplicity of gigahertz digital printed-circuit boards can be combined with controlled impedance gas-tight connections between boards together with separate boards for power management and analog functions. The overall assembly (7) is extremely rugged and suitable to go anywhere. The connector (6) is mechanically regular and suitable for robotic construction, testing and assembly.

### BRIEF DESCRIPTION OF FIGURES

The invention is described by appended claims in relation to a preferred embodiment with reference to the following figures that are explained briefly as follows:

FIG. 1 is a view of a single connector (6) used in the Printed Circuit Assembly (7) that allows mechanical and electrical interface between two printed circuit boards.

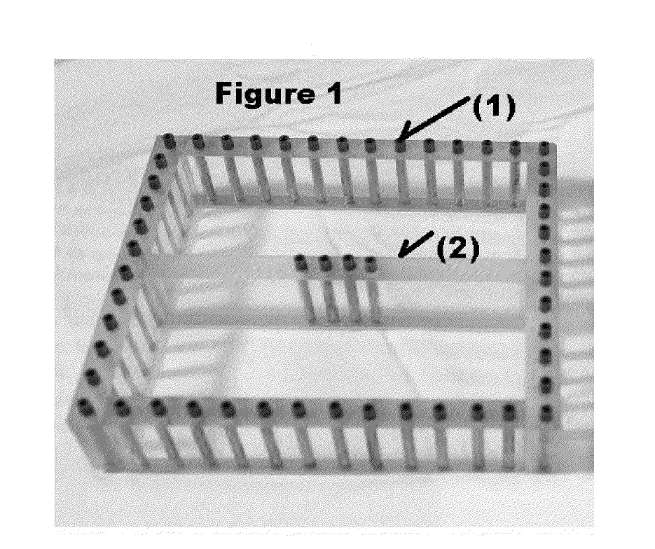

FIG. 2. is a view of a topmost connector (6) in a Printed Circuit Assembly (7) showing one of the threaded bolts (3) used in each column of connecting cylinders (1).

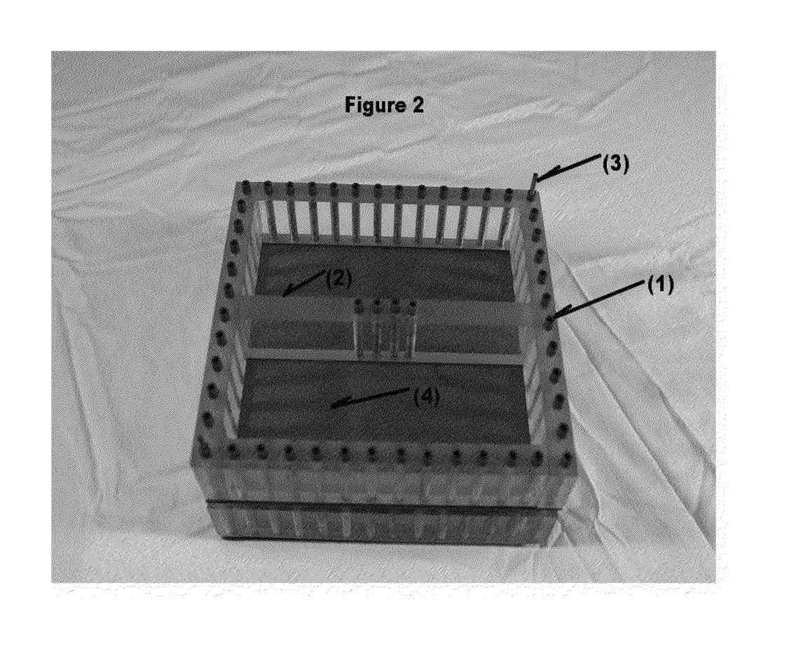

FIG. 3 is a view of a partially built Printed Circuit Assembly (7) showing one of the threaded bolts (3) used in each column of connecting cylinders (1) and one threaded nut (5) used to secure each column of connecting cylinders (1) with a torque set to make gas-tight connections.

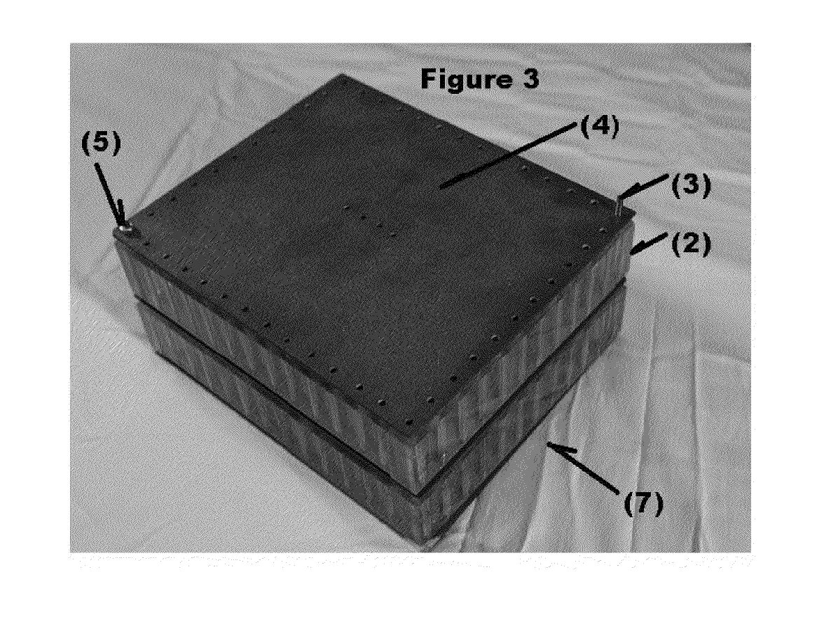

FIG. 4 is a view of two connectors (6) showing both a horizontal and a vertical orientation that is possible for an assembly (7). In many applications, the vertical connector orientation is preferred for heat flow purposes.

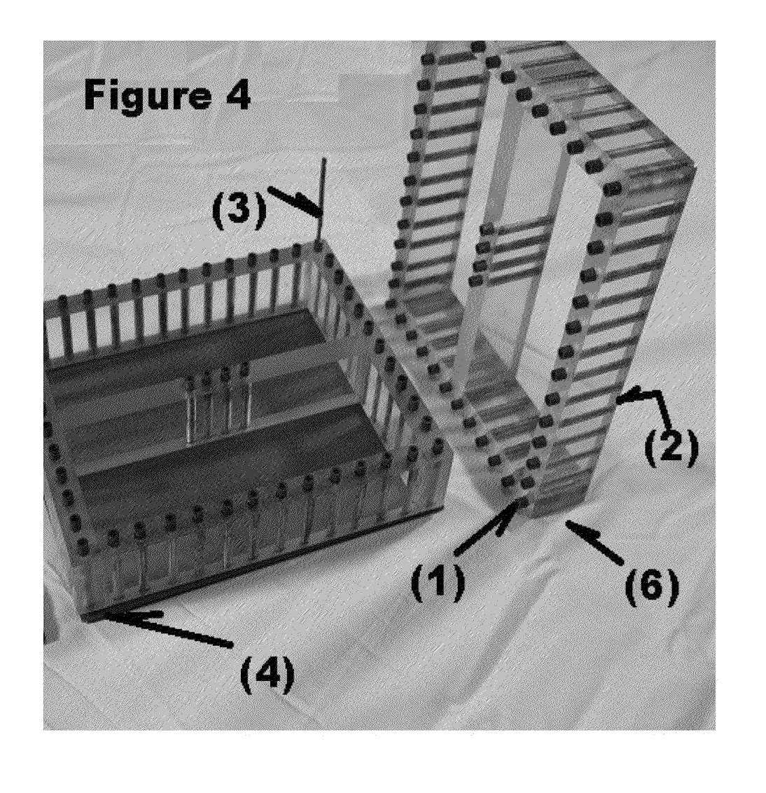

### DESCRIPTION OF PREFERRED EMBODIMENT

### Reference Numerals

Listed numerically below with reference to the figures are terms used to describe features of the invention. The terms and numbers assigned to them are used throughout this description.

1. Conducting or non-conducting threaded or non-threaded standoff cylinder.

2. Non-conducting structural matrix mechanically capturing standoff cylinders (1) to create columns.

3. Threaded conducting or non-conducting bolt within each column of standoff cylinders (1).

4. Printed circuit board of one or more copper layers drilled or punched to allow bolts (3) to pass through.

5. Threaded conducting or non-conducting nut to apply controlled torque to a column of standoff cylinders (1).

6. Connector capturing equal length standoff cylinders (1) in a precision alignment within a non-conducting matrix (2).

7. Assembled stack of connectors (6) and printed circuit boards (4).

The preferred embodiment of the system is to build and test each printed circuit board (4) separately followed by final assembly and test of the stack (7) and then placement of the complete unit into a suitable enclosure. This sequence allows use of surface mount and related robotic technology. The overall regular geometry allows for use of optimizing software to place components on boards to control interconnection distances, heat flow and magnetic shielding. Threaded cylinders (1) allow a threaded conducting bolt (3) to pass either power or a signal between two or more printed circuit boards (4) within a cylinder.

What is claimed:

1. A Printed Circuit Assembly comprising:
One or more connectors each composed of a non-conducting matrix that mechanically captures a multiplicity of conducting or non-conducting equal-length standoff cylinders with each cylinder either threaded or smooth.

2. A Printed Circuit Assembly of claim 1 wherein:
Two or more printed circuit boards are joined with each pair of boards sharing a connector having a multiplicity of standoff cylinders allowing controlled torque of each cylinder column passing power or signal between boards.

3. A Printed Circuit Assembly of claim 2 wherein:
A multiplicity of printed-circuit boards with each pair joined by connectors forming gas-tight connections with standoff cylinders having controlled torque and impedance to form an integrated system of power and signal.
